(19) United States
(12) Patent Application Publication
(10) Pub. No.: US 2026/0082994 A1
(43) Pub. Date: Mar. 19, 2026

(54) SEMICONDUCTOR DEVICE AND PROCESS FOR MAKING THE SAME

(71) Applicant: Intel Corporation, Santa Clara, CA (US)

(72) Inventors: Chun-Chiang KUO, Kaohsiung City (TW); DerChang KAU, Cupertino, CA (US); Kai Chiang WU, Hsinchu City (TW)

(21) Appl. No.: 18/884,172

(22) Filed: Sep. 13, 2024

(51) Int. Cl. H01L 25/16; H01L 23/48; H01L 25/00; H10B 80/00

(52) U.S. Cl. CPC H10W 90/00; H10W 20/20; H10B 80/00

(57) ABSTRACT

In some aspects, a semiconductor device is provided. The semiconductor device includes a plurality of core dies; and a plurality of passive dies, each of the plurality of passive dies corresponding to one respective core die of the plurality of core dies, wherein each of the plurality of passive dies comprises a plurality of through-silicon vias configured to connect the plurality of core dies with a controller die, and wherein the plurality of core dies and the plurality of passive dies are arranged vertically into first to Nth tiers in a manner that each tier of the first to Nth tiers includes a core die of the plurality of core dies and a corresponding passive die of the plurality of passive die placed side-by-side horizontally.

### TECHNICAL FIELD

The present disclosure generally relates to a semiconductor device and a process for making the same, in particular, a memory unit and a process for making a memory unit.

### BACKGROUND

In contemporary memory architectures such as High Bandwidth Memory (HBM), the integration of multiple tiers of memory dies stacked vertically introduces significant technical challenges and cost implications. Each memory tier necessitates a complex network of Through-Silicon Vias (TSVs) for vertical interconnects, leading to increased die size and manufacturing costs. The unique layout requirements for TSVs and Redistribution Layers (RDL) across different memory tiers further contribute to design complexity and escalate the expense of photolithography masks and process handling. For instance, in practical implementations like HBM2, which includes multiple stacked dies, the substantial number of TSVs per die consumes additional die area and amplifies production costs. These challenges pose limitations on the scalability of stacked memory technologies, impacting their feasibility for expanding to accommodate more tiers in future designs.

Therefore, there exists a need to provide an improved semiconductor device and a process for making the same.

### BRIEF DESCRIPTION OF THE DRAWINGS

The accompanying drawings serve to provide an understanding of non-limiting aspects. Further non-limiting aspects and many of the intended advantages will become apparent directly from the following detailed description. The elements and structures shown in the drawings are not necessarily shown to scale relative to each other. Like reference numerals refer to like or corresponding elements and structures. Non-limiting aspects of the present disclosure will be better understood by one of ordinary skill in the art from the following detailed description and in conjunction with the drawings, in which:

FIG. 1 is a block diagram showing a semiconductor device according to various non-limiting aspects of the present disclosure;

FIG. 2 is a schematic diagram showing a cross-sectional view of a semiconductor device according to various aspects of the present disclosure;

FIG. 3 is a schematic diagram showing a cross-sectional view of a semiconductor according to various aspects of the present disclosure;

FIG. 4 is a schematic diagram showing a cross-sectional view of a non-limiting semiconductor device of the semiconductor device of FIG. 3;

FIG. 5A is a schematic diagram showing a cross-sectional view of a non-limiting semiconductor device of the semiconductor device of FIG. 3;

FIG. 5B shows an enlarged schematic diagram of FIG. 5A;

FIG. 6 is a flow chart showing a process for making a semiconductor device according to various aspects of the present disclosure;

FIGS. 7A to 7D show schematic diagrams for fabricating a plurality of core dies/controller die/base die according to various aspects of the present disclosure;

FIGS. 8A to 8E show schematic diagrams for fabricating a plurality of passive dies, each of which has a plurality of through-silicon vias according to various aspects of the present disclosure;

FIGS. 9A to 9G and 9G′ show schematic diagrams for making a semiconductor device according to various aspects of the present disclosure; and

FIGS. 10A to 10D show schematic diagrams for making a semiconductor device according to various aspects of the present disclosure.

### DETAILED DESCRIPTION

Aspects described below in the context of a method are analogously valid for the respective element, device, apparatus, or system, and vice versa. Furthermore, it will be understood that the aspects described below may be combined, for example, a part of one aspect may be combined with a part of another aspect, and a part of one aspect may be combined with a part of another aspect.

It should be understood that the singular terms “a”, “an”, and “the” include plural references unless context clearly indicates otherwise. Similarly, the word “or” is intended to include “and”unless the context clearly indicates otherwise.

It will be further understood that the terms “comprise” (and any form of comprise, such as “comprises” and “comprising”), “have” (and any form of have, such as “has” and “having”), “include” (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

Approximating language, as used herein throughout the specification and claims, may be applied to modify any quantitative representation that could permissibly vary without resulting in a change in the basic function to which it is related. Accordingly, a value modified by a term or terms, such as “about,” “substantially”, is not limited to the precise value specified but within tolerances that are acceptable for operation of the aspect for an application for which it is intended. In some instances, the approximating language may correspond to the precision of an instrument for measuring the value.

The term “exemplary” may be used herein to mean “serving as an example, instance, or illustration”. Any aspect or design described herein as “exemplary” is not necessarily to be construed as preferred or advantageous over other aspects or designs.

The terms “at least one” and “one or more” may be understood to include a numerical quantity greater than or equal to one (e.g., one, two, three, four, [ . . . ] , etc.). The term “a plurality” may be understood to include a numerical quantity greater than or equal to two (e.g., two, three, four, five, [ . . . ] , etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of listed elements.

The term “first”, “second”, “third” detailed herein are used to distinguish one element from another similar element and may not necessarily denote order or relative importance, unless otherwise stated. For example, a first transaction data, a second transaction data may be used to distinguish two transactions based on two different foreign currency exchange.

The term “computing device” may be used herein to mean any suitable device and/or system such as, by way of example and not as a limitation, a personal computer, a laptop, a game console, a mobile phone and the like.

As used herein, the term “connect/connected/connection” may refer to a wired or wireless communication link formed between electronic devices that enables data transmission.

The terms “processor” as used herein may be understood as any kind of entity that allows handling data. The data may be handled according to one or more specific functions executed by the processor or embedded controller. Further, a processor or embedded controller as used herein may be understood as any kind of circuit, e.g., any kind of analog or digital circuit. A processor or an embedded controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), etc., or any combination thereof. Any other kind of implementation of the respective functions, which will be described below in further detail, may also be understood as a processor, embedded controller, or logic circuit. It is understood that any two (or more) of the processors, embedded controllers, or logic circuits detailed herein may be realized as a single entity with equivalent functionality or the like, and conversely that any single processor, embedded controller, or logic circuit detailed herein may be realized as two (or more) separate entities with equivalent functionality or the like.

The term “memory” detailed herein may be understood to include any suitable type of memory or memory device, e.g., a hard disk drive (HDD), a solid-state drive (SSD), a flash memory, etc.

Terraced Chiplet Cubing (TCC) is an advanced 3D Integrated Circuit (3DIC) technology that significantly enhances cost efficiency, modularity, reusability, and scaling coherence compared to traditional Through-Silicon Via (TSV) and backside interconnect (BSI) methods. By utilizing an economical silicon interposer to replace TSVs in active silicon chiplets, TCC may maximize active silicon utilization and reduce manufacturing costs. It may eliminate the need for keep-out zones, allowing more flexible and efficient circuit placement. TCC's design may enable the reuse of chiplets (or dies) without redesigning interface circuitry, facilitating the addition of memory capacity and other components without significant redesign efforts. This modular approach may support the integration of diverse chiplets (or dies), including compute subsystems with DRAM, SRAM, logic, and mixed-signal chips, within a single stack, ensuring consistent performance and integration efficiency across different technology nodes. TCC's ability to integrate chiplets (or dies) with and without TSVs or BSI may offer a versatile platform for high-performance computing, consumer electronics, automotive applications, and IoT devices, making it a highly flexible and efficient solution for modern semiconductor design and integration.

Various non-limiting aspects described herein seek to provide an advantageous and efficient semiconductor device (e.g., memory unit). The semiconductor device may include a plurality of core dies, and a plurality of passive dies. At least one passive die of the plurality of passive dies may correspond to a respective core die of the plurality of core dies that is disposed at a same tier as the at least one passive die. That is, the at least one passive die may be arranged horizontally side-by-side with the respective core die. The plurality of core dies may not include through-silicon vias and instead the plurality of separate passive dies may include a plurality of through-silicon vias connecting the plurality of separate passive dies to each other and to the plurality of core dies and configured to connect the plurality of core dies with a controller die. The controller die may be included in the semiconductor device or be an external compute die. Each pair of a core die and at least one passive die may form a tier. A subsequent tier of core die and passive die may be staggered with respect to a previous tier of core die and passive die so as to form a terrace-shape. This approach may enable a vertical (data) connection between the core die in the subsequent tier (e.g. the core die faced down to the previous tier) and a through-silicon via of the passive die in the previous tier (e.g. backside of the through-silicon via). That is, a core die may have interface ports on a bottom side of the core die and a core die in the subsequent tier may be arranged over a passive die in the previous tier so that a TSV of the passive die may connect to an interface port of the core die. Backside preparation (e.g. bump formation) for the core dies and the base die may not be needed.

In some aspects, a controller die may be provided on top of the topmost tier, and the core dies may be connected to the controller die by the through-silicon vias of the passive dies and copper traces formed in the passive dies. This approach may help heat dissipation. In some non-limiting aspects, the controller die may be placed on the at least one passive die of the topmost tier.

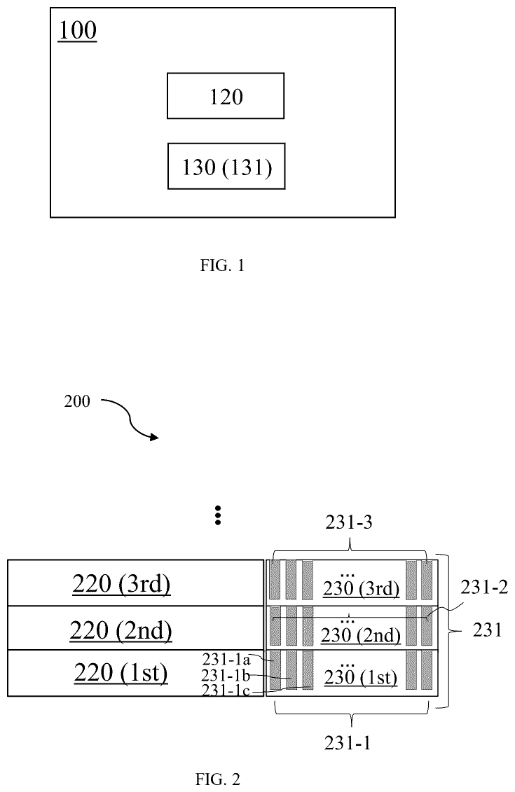

FIG. 1 is a block diagram showing a semiconductor device 100 according to various non-limiting aspects of the present disclosure. The semiconductor device 100 may include a 3D-packaged semiconductor device 100 integrating multiple semiconductor components, such as CPUs, GPUs, and specialized processors (like XPUs), into a single vertical stack. The 3D-packaged semiconductor device may enhance performance by reducing the distance data travels between components, thereby decreasing latency and improving speed. Additionally, the 3D-packaged semiconductor device may lower power consumption due to the shorter interconnects and more efficient use of space. Through-silicon vias (TSVs) and Integrated Fan-Out (InFO) may be used to achieve these improvements, enabling high-performance consumer electronics, data centers, and AI accelerators. By combining different processing units in a compact, stacked design, the 3D-packaged device may provide a powerful and efficient solution for modern computing needs.

In some embodiments, the 3D-packaged semiconductor device 100 may be a memory unit. As used herein, the term “memory unit” may refer to a component in computing systems, responsible for storing and retrieving digital data. It may play a pivotal role in facilitating rapid access to information during computing tasks, bridging the gap between processing units and long-term storage devices. Memory units may encompass both volatile types, such as RAM, which offer fast access speeds but require continuous power to maintain data, and non-volatile types like ROM and flash memory, which retain data even without power. The memory unit may include a High Bandwidth Memory (HBM) unit in advanced computing systems. The HBM unit may include vertically stacking multiple Dynamic Random Access Memory (DRAM) dies that are connected using Through-Silicon Vias (TSVs). A memory unit with a tiered and staggered 3D stacking approach may reduce the TSV area penalty on the active dies while enabling fast communication between memory layers, crucial for applications demanding high bandwidth and low latency, such as graphics-intensive tasks in gaming and high-performance computing environments.

According to various aspects of the present disclosure, the semiconductor device 100 may include a plurality of core dies 120, including first to Nth core dies; and a plurality of passive dies 130, including first to Nth passive dies, N being an integer greater than or equal to 2. Each of the plurality of passive dies 130 may correspond to one respective core die of the plurality of core dies 120. In other words, a respective core die (e.g. the i-th core die, 1≤i≤N) of the plurality of core dies 120 may be associated with a corresponding passive die (e.g. the i-th passive die, 1≤i≤N) of the plurality of passive dies 130. The plurality of passive dies 130 may include a plurality of through-silicon vias 131 including 131-1, 131-2, . . . , 131-N, connecting the plurality of core dies 120 with a controller die (not shown). In other words, the corresponding passive die (e.g. the i-th passive die, 1≤i≤N) may include a plurality of through-silicon vias 131-i, and respective through-silicon via(s) of the plurality of through-silicon vias 131-i may connect the core die (e.g. the (i+1)-th core die, 1≤i≤N) in the subsequent tier (e.g. the (i+1)-th tier), with the controller die.

As used herein, the term “core die” may refer to the main die or central die that handles primary processing tasks or contains the main processing units (cores). In the context of DRAM memory unit or modules, the core die(s) may be the main die(s) containing the bulk of the memory cells and basic control circuits. In the context of various aspects of the present disclosure, the core die may be used interchangeably with “active die” and refer to a die or chiplet engaged in active operations including reading or writing data.

As used herein, the term “base core die” may refer to a core die placed at the foundational layer and play a crucial role in the structural and operational integrity of the memory unit or module. In the context of multi-die DRAM packages, the base core die may be positioned at the bottom of the stack and provide essential support for stacking additional memory dies above it. The base core die may include interconnects such as Through-Silicon Vias (TSVs) that facilitate communication between the various dies and with an external memory controller. Additionally, the base core die may contain memory cells that contribute to the overall storage capacity of the module. While it primarily focuses on maintaining structural integrity and ensuring efficient data and power routing within the multi-die package, the base core die may also incorporate minimal control logic to support its foundational role.

As used herein, the term “controller die” may be used interchangeably with “logic die” and refer to a die that contains the memory controller circuitry that manages the operations of the memory dies and communicates with the external memory controller or processor, translating commands into actions for the memory dies. The controller die may be positioned at the base of the stack (i.e. as a base die). The controller die may be positioned at the top of the stack. The controller die may be an external compute die and the core dies (e.g. Low Power Double Data Rate (LPDDR) memory cube) may connect to the controller die through the substrate or interposer interconnection.

According to various aspects of the present disclosure, the plurality of core dies 120 may be void of through-silicon vias. In other words, the plurality of core dies 120 may not include any through-silicon vias and instead the corresponding plurality of passive dies 130 may include through-silicon vias 131 for connecting the plurality of core dies 120 to a controller die. The semiconductor device 100 may allow a reduction of space in the plurality of core dies 120 by arranging the through-silicon vias 131 in the (cheaper) plurality of passive dies 130.

According to various aspects of the present disclosure, the plurality of core dies 120 may be identical to each other. This may be realized by arrangements of the through-silicon vias 131 in the plurality of passive dies 130. Accordingly, one set of masks may be used for fabricating the plurality of core dies 120, thereby saving core dies costs and enabling high scalability of capacity.

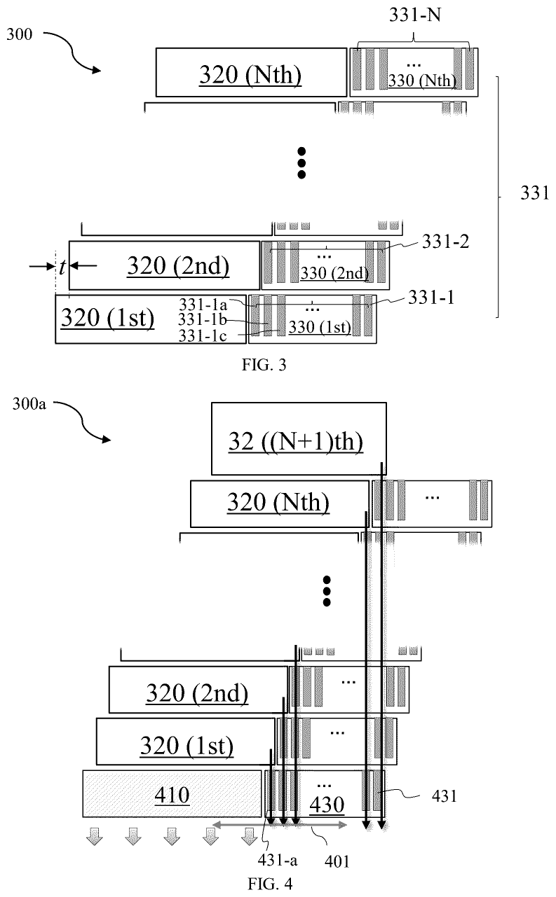

According to various aspects of the present disclosure, the plurality of core dies 120 may be tiered (e.g. stacked vertically) and the plurality of passive dies 130 may be correspondingly tiered (e.g., stacked vertically) into first to Nth tiers in a manner that the respective core die of the plurality of core dies 120 and the corresponding passive die of the plurality of passive die 130 are arranged side-by-side horizontally in each tier of the first to Nth tiers, for example, as shown in FIG. 2 and FIG. 3. In other words, the plurality of core dies 120 and the plurality of passive dies 130 may be arranged vertically into first to Nth tiers in a manner that each tier of the first to Nth tiers includes a core die of the plurality of core dies 120 and a corresponding passive die of the plurality of passive die 130 placed side-by-side horizontally. The plurality of core dies 120 and the plurality of passive dies 130 may be placed faced-down in a stack to form the first to Nth tiers in a manner that a subsequent (e.g., immediate upper) core die (e.g. the (i+1)-th core die, 1≤i≤N) of the plurality core dies 120 in a subsequent (e.g., immediate upper) tier (e.g. the (i+1) th-tier) may connect to a topside of a plurality of silicon-through vias of a previous (e.g., immediate lower) passive die (e.g. the i-th core die, 1≤i≤N) of the plurality passive dies 130 in a previous (e.g., immediate lower) tier (e.g. the i-th tier).

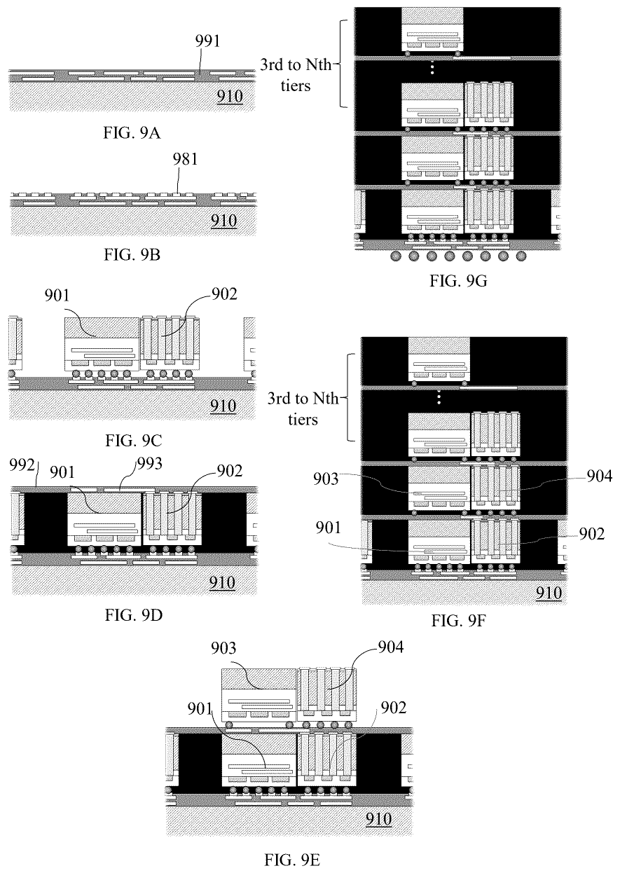

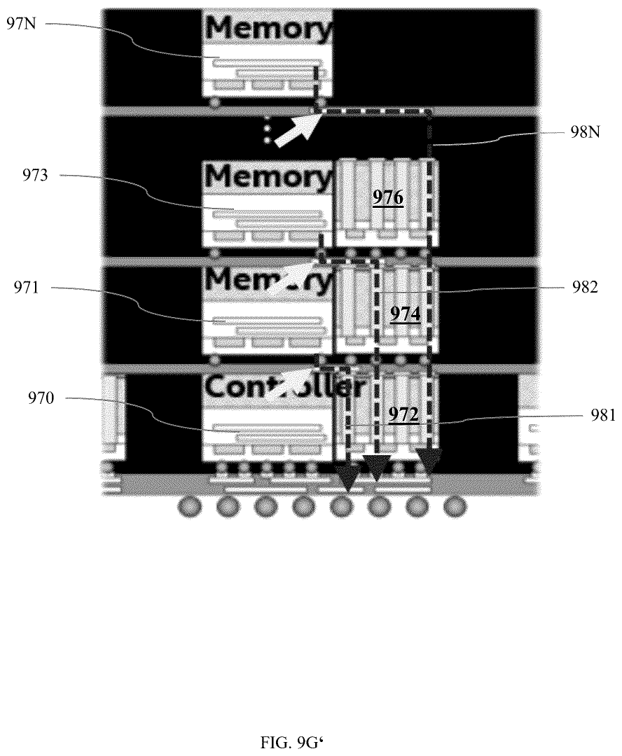

FIG. 2 is a schematic diagram showing a cross-sectional view of a semiconductor device 200 according to various aspects of the present disclosure. The semiconductor device 200 may include a plurality of core dies 220, including first to Nth core dies (first to third core dies shown); and a plurality of passive dies 230, including first to Nth passive dies (first to third passive dies shown), N being an integer greater than or equal to 2. Each of the plurality of passive die 230 may correspond to one respective core die of the plurality of core dies 220. For example, the first core die 220(1st) of the plurality of core dies 220 may be associated with the first passive die 230(1st) of the plurality of passive dies 230; the second core die 220(2nd) of the plurality of core dies 220 may be associated with the second passive die 230(2nd) of the plurality of passive dies 230; and so forth. The plurality of core dies 220 may be identical to each other. Each of the plurality of passive dies 230 may include a plurality of through-silicon vias, e.g., 231-1, 231-2, . . . or 231-N (collectively 231) aligned to form vertical interconnects, for connecting the plurality of core dies 220 with a controller die. For example, the first passive die 230(1st) may include a plurality of through-silicon vias 231-1, and respective through-silicon via(s) of the plurality of through-silicon vias 231-1 may connect to the second core die 220(2nd) through one or more lines in a metal layer placed between the first and second tier (e.g. through one or more metal lines 993 as shown FIG. 9D). The respective through-silicon via(s) of the plurality of through-silicon vias 231-1 may connect to a controller die through one or more redistribution lines in a redistribution layer placed under the first tier (e.g., through one or more redistribution lines 991 as shown in FIG. 9A). The semiconductor device 200 may include a controller die. The semiconductor device 200 may be a memory unit.

In some aspects of the present disclosure, the semiconductor device 200 may further include a plurality of second passive dies, and each of the plurality of second passive die may correspond to one respective core die of the plurality of core dies 220.

According to various aspects of the present disclosure, the plurality of core dies 220 may be vertically stacked and the plurality of passive dies 230 may be correspondingly vertically stacked into first to Nth tiers in a manner that a respective core die (e.g., i-th tier) of the plurality of core dies 220 and a corresponding passive die (e.g., i-th tier) of the plurality of passive die 230 are arranged horizontally side-by-side in each tier of the first to Nth tiers. Each vertical tier of the first to Nth tiers may include a core die of the plurality core dies 220 and a corresponding passive die of the plurality of passive dies 230. That may mean that a subsequent core die (e.g. a second core die) is placed on top of a previous core die (e.g. a first core die) and a subsequent passive die (e.g. a second passive die) is placed on top of a previous passive die (e.g. the first passive die). In other words, the plurality of core dies 220 may be aligned vertically and the plurality of passive dies 230 may be aligned vertically too. That may mean that a respective through-silicon via (e.g. a second through-silicon via 231-1b) of a plurality of through-silicon vias (e.g. 231-1) of a previous passive die (e.g. the first passive die) connects to a respective through-silicon via (e.g. a second through-silicon via 231-2b) of a plurality of through-silicon vias (e.g. 232-2) of a subsequent passive die (e.g. a second passive die). In other words, the plurality of through-silicon vias (e.g. 231-1) of the previous passive die (e.g. the first passive die) may be respectively aligned with the plurality of through-silicon vias (e.g. 232-2) of the subsequent passive die (e.g. a second passive die) so as to provide vertical paths for data and power transmission. For purposes of avoiding clutter in the drawings, only the first, second and third through-silicon vias 231-1a, 231-1b and 231-1c of the plurality of through-silicon vias 231-1 of the first passive die of the plurality of passive dies 230 are labelled in FIG. 2. A metal layer or redistribution layer including lateral metal lines may connect a core die (one or more interface ports of a core die) to a passive die (one or more corresponding through-silicon vias of a passive die). For example, a core die in a subsequent tier may be connected to a passive die in a previous tier by metal lines in a metal layer or a redistribution layer placed between the previous tier and the subsequent tier.

FIG. 3 is a schematic diagram showing a cross-sectional view of a semiconductor device 300 according to various aspects of the present disclosure. The semiconductor device 300 may include a plurality of core dies 320, including first to Nth core dies (first, second and Nth core dies shown); and a plurality of passive dies 330, including first to Nth passive dies (first, second and Nth passive dies shown), N being an integer greater than or equal to 2. Each of the plurality of passive die 330 may correspond to a respective core die of the plurality of core dies 320. For example, the first core die of the plurality of core dies 320 may be associated with the first passive die of the plurality of passive dies 330; the second core die of the plurality of core dies 320 may be associated with the second passive die of the plurality of passive dies 330; and so forth. The plurality of core dies 320 may be identical. Each of the plurality of passive dies 330 may include a plurality of through-silicon vias 331-1, 331-2, . . . , 331-N (collectively 331) for connecting the plurality of core dies 320 with a controller die. For example, the Nth passive die may include a plurality of through-silicon vias 331-N, and respective through-silicon via(s) of the plurality of through-silicon vias 331-N may connect the Nth core die with the controller die.

According to various aspects of the present disclosure, for each integer k, 2≤k≤N, the kth core die of the kth tier may be shifted laterally by a predetermined displacement from the (k−1)th core die of the (k−1)-th tier, denoted as t between the first core die and the second core die in FIG. 3. The plurality of core dies 320 may be vertically stacked and the plurality of passive dies 330 may be correspondingly vertically stacked into first to Nth vertical tiers in a manner that each respective core die of the plurality of core dies 320 and the corresponding passive die of the plurality of passive die 330 are arranged horizontally side-by-side in each vertical tier of the first to Nth tiers. Each vertical tier of the first to Nth tiers may include a core die of the plurality core dies 320 and a corresponding passive die of the plurality of passive dies 330. That may mean that a subsequent core die (e.g. the second core die) is placed on top of both a previous core die (e.g. the first core die) and a previous passive die (e.g. the first passive die), and that a subsequent passive die (e.g. the second passive die) is placed on top of a previous passive die (e.g. the first passive die). That is, a subsequent core die may overlap both a previous core die and a previous passive die, and a subsequent passive may overlap only the previous passive die and not the previous core die. In other words, the plurality of core dies 320 and the plurality of passive dies 330 may be respectively vertically stacked with a horizontal offset in a terraced-shape or staggered arrangement.

A side edge of a subsequent core die (e.g. the second core die) of the plurality of core dies 320 may be shifted relative to a side edge of a previous core die (e.g. the first core die) of the plurality of core dies 320 by the predetermined displacement t. That is, there may be a lateral distance t between the side edge of the subsequent core die (e.g. the second core die) of the plurality of core dies 320 and the side edge of the previous core die (e.g. the first core die) of the plurality of core dies 320. For example, in a portion where a subsequent passive die (e.g. the second passive die) overlaps a previous passive die (e.g. the first passive die), one or more through-silicon vias (e.g. a second through-silicon via, 331-1b) of a plurality of through-silicon vias (e.g. 331-1) of a previous passive die (e.g. the first passive die) may connect to one or more aligned through-silicon vias (e.g. a first through-silicon via, 331-2a) of a plurality of through-silicon vias (e.g. 331-2) of a subsequent passive die (e.g. the second passive die). For example, in a portion where a subsequent core die (e.g. the second core die) overlaps a previous passive die (e.g. the first passive die), one or more first through-silicon vias (e.g. 331-1a) of the plurality of through-silicon vias (e.g. 331-1) of the previous passive die (e.g. the first passive die in the first tier) may connect to the subsequent core die (e.g. the second core die in the second tier) of the plurality of core dies 320. Stated differently, the kth core die may be connected to one or more through-silicon vias of the plurality of through-silicon vias (331-(k−1)) of the (k−1)-th passive die of the plurality of passive dies 330. For purposes of avoiding clutter in the drawings, only the first, second and third through-silicon vias 331-1a, 331-1b and 331-1c of the plurality of through-silicon vias 331-1 of the first passive die of the plurality of passive dies 330 are labelled in FIG. 3. Additionally, to avoid further clutter, each of the first, second and third through vias 331-1a, 331-1b and 331-1c shown may represent a via of a set of one or more through-silicon vias. Each core die 320 may include M interface ports (M being an integer >=1)(e.g., 1028 interface ports). For example, the second core die 320(2nd) may include M interface ports. In such case, via 331-1a of the first passive die 330(1st) may be one via of a set of M through-silicon vias for connecting to the M interface ports of the second core die 320(2nd). The other vias of the set are not shown. The semiconductor device 300 may include a controller die (not shown). The semiconductor device 300 be a memory unit.

The semiconductor devices 200, 300 may include the same or similar features of the semiconductor device 100. Accordingly, features that are described in the context of the semiconductor device 100 may correspondingly be applicable to the same or similar features in the semiconductor devices 200, 300 and vice versa. Furthermore, additions and/or combinations and/or alternatives as described for a feature in the context of the semiconductor device 100 may correspondingly applicable to the same or similar feature in the semiconductor devices 200, 300 and vice versa.

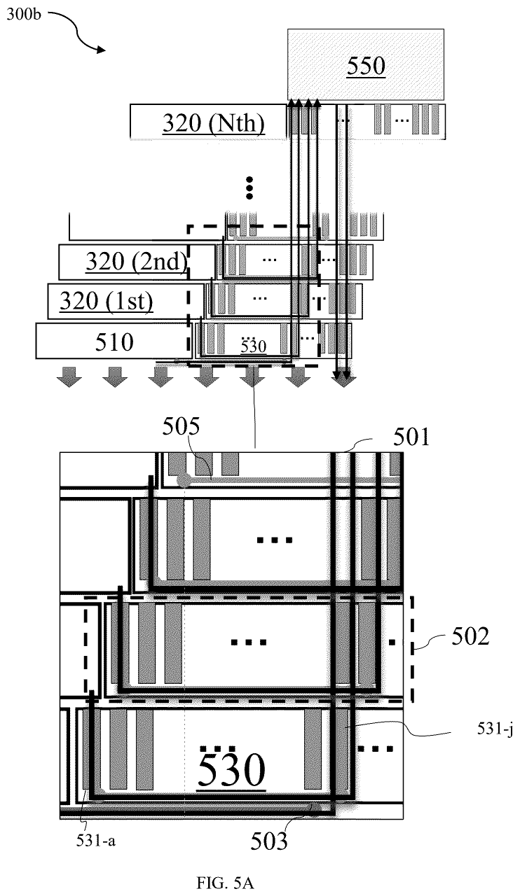

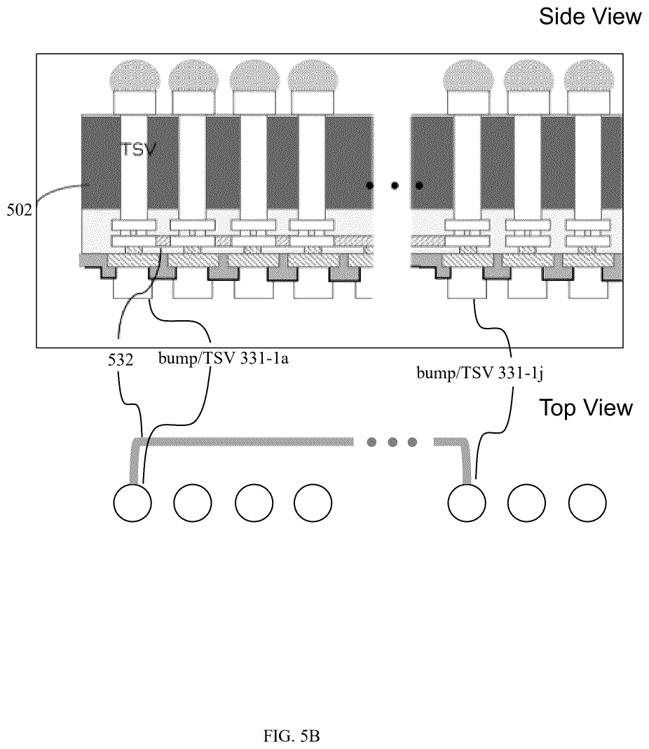

FIGS. 4 and 5A are schematic diagrams showing cross-sectional views of two non-limiting semiconductor devices 300a, 300b of the semiconductor device 300, respectively. Inset 501 of FIG. 5A shows an enlarged portion of the semiconductor device 300b.

The semiconductor device 300a (e.g. a High Bandwidth Memory (HBM) memory cube) as shown in FIG. 4 may include a controller die 410 (as a base die) and a base passive die 430 corresponding to the controller die 410 in a manner that the controller die 410 and the corresponding base passive die 430 are arranged side-by-side horizontally. The first core die of the plurality core dies 320 may be shifted by a predetermined horizontal displacement from the controller die 410. That may mean that the first core die is placed on top of both the controller die 410 and the base passive die 430, and the first passive die is placed only on top of the base passive die 430. That may mean that a first through-silicon via 431-a of a plurality of through-silicon vias 431 of the base passive die 430 may connect to the first core die 320(1st) of the plurality of core dies 320. For purposes of avoiding clutter in the drawings, only one through-silicon via 431-a of the plurality of through-silicon vias 431 of the base passive die 430 is labelled in FIG. 4. Additionally, to avoid further clutter, via 431-a shown may represent a via of a set of one or more through-silicon vias. Each core die 320 may include M interface ports (M being an integer >=1)(e.g., 1028 interface ports). For example, the first core die 320(1st) may include M interface ports. In such case, via 431-a of the base passive die 430 may be one via of a set of M through-silicon vias for connecting to the M interface ports of the first core die 320(1st). The other vias of the set are not shown. The semiconductor device 300a may further include a top core die 32 placed at an (N+1) tier, shifted by the predetermined horizontal displacement from the Nth core die 320 (320(Nth)) placed at the Nth tier. The top core die 32 may not have a corresponding passive die. The plurality of core dies 320 and the unpaired top core die 32 may be connected to a redistribution layer (RDL) 401 (e.g. a Fan-Out RDL) through the base passive die 430 by the plurality of through-silicon vias of the base passive die 430 and the plurality of passive dies 330. The redistribution layer 401 extends laterally under the controller die 410 and base passive die 430.

The semiconductor device 300b as shown in FIG. 5A may include a base core die 510 (i.e. a core die placed at the bottom) and a base passive die 530 corresponding to the base core die 510 in a manner that the base core die 510 and the corresponding base passive die 530 are arranged side-by-side horizontally.

According to various non-limiting embodiments, the semiconductor device 300b may include a controller die 550 placed on top of the Nth passive die (330(Nth)) of the plurality of passive dies 330. The controller die (550) placed at the top enhances thermal dissipation efficiency. The first core die (320(1st)) of the plurality core dies 320 may be shifted by a predetermined horizontal displacement from the base core die 510. That may mean that the first core die is placed on top of both the base core die 510 and the base passive die 530, and the first passive die (330(1st)) is placed on top of only the base passive die 530. For example, that may mean that a first through-silicon via 531-a of a plurality of through-silicon vias 531 of the base passive die 530 may connect to the first core die (320 (1st)) of the plurality of core dies 320 as shown in the inset 501 of FIG. 5A. A central through-silicon via 531-j of a plurality of through-silicon vias 531 of the base passive die 530 may connect to the controller die 550. For purposes of avoiding clutter in the drawings, only a few of the through-silicon vias 531-a, 531-j of the plurality of through-silicon vias 531 of the base passive die 530 are labelled in FIG. 5A. Additionally, to avoid further clutter, each of the vias 531-a, 531-j shown may represent a via of a set of one or more through-silicon vias. Each core die 320 may include M interface ports (M being an integer >=1)(e.g., 1028 interface ports). For example, the first core die 310(1st) may include M interface ports. In such case, via 531-a of the base passive die 530 may be one via of a set of M through-silicon vias for connecting to the M interface ports of the first core die 310(1st). Correspondingly, via 531-j may also be one via of a set of M through-silicon vias for connecting to the controller die 550. The other vias of the set are now shown. Consequently, lateral line 503 may represent a lateral line of a set of M lateral lines for respective couplings of the vias not shown. The central through-silicon via 531-j of the base passive die 530 may be arranged rightward of the one or more through-silicon vias of the base passive die configured to connect to the uppermost core die (e.g., 320 (Nth)). The central through-silicon via 531-j of the base passive die may be aligned with the left-most through-silicon via of the uppermost passive die (e.g., 330(Nth)).

FIG. 5B shows an enlarged schematic diagram of area 502 of FIG. 5A, illustrating the plurality of through-silicon vias of the first passive die 330 (1st). Each passive die of the plurality of passive dies 330 (except the passive die in direct connection with the controller die 550) may include a metal layer (e.g., Back-End-of-Line (BEOL) metal layer) to help carry signals laterally from a left-most through-silicon via 331-1a to a central through-silicon via 331-1j, so that signals from each tier of the core die may be communicated to the controller die 550. For example, a signal from a core die in a subsequent tier travels down a left-most through-silicon via of a passive die in a previous tier to a metal layer and then travels up a central through-silicon via of the passive die to a through-silicon via of a passive die in the subsequent tier. The central through-silicon via is overlapped by the controller die 550. For purposes of avoiding clutter in the drawings, only a few of the through-silicon vias 331-1a, 331-1j of the plurality of through-silicon vias are labelled in FIG. 5B. Additionally, to avoid further clutter, each of the vias 331-1a, 331-1j shown may represent a via of a set of one or more through-silicon vias. Each core die 320 may include M interface ports (M being an integer >=1)(e.g., 1028 interface ports). In such case, via 331-1a of the passive die may be one via of a set of M through-silicon vias for connecting to the M interface ports of a core die. Correspondingly, via 531-j may also be one via of a set of M through-silicon vias for connecting to the controller die 550. The other vias of the set are not shown. Consequently, the lateral line in metal layer 532 may represent a lateral line of a set of M lateral lines for respective couplings of the vias not shown. The central through-silicon via 331-1j of the passive die in the first tier (e.g., 330 (1st)) may be arranged rightward of the through-silicon via of the passive die in the first tier configured to connect the central through-silicon via 531-j of the base passive die to the controller die 550. In the base tier, lateral transmission of signals between the base core die 510 (e.g., memory die) and the base passive die 530 is carried by a bottom redistribution layer including a fan-out RDL line 503.

As shown in FIG. 5B, the first through-silicon via 331-1a of a plurality of through-silicon vias of the first passive die 330 (1st) may then connect to a central through-silicon via (331-1j) (e.g. a (M×N+1)-th through-silicon via) of a plurality of through-silicon vias of the first passive die 330 (1st) by the BEOL (Back-End of Line) metal layer (e.g. copper interconnect) included in the first passive die 330 (1st). The central through-silicon via (e.g. a (N+1)-th through-silicon via) of a plurality of through-silicon vias of the first passive die 330 (1st) may then connect to the controller 550 through aligned through-silicon vias of the plurality passive dies 330 at subsequent tiers. The plurality of core dies 320 may be similarly connected to the controller die 550 through the plurality of passive dies 330 by the plurality of through-silicon vias of the base passive die 530, i.e. through a metal line in a metal layer (e.g., BEOL) of each corresponding passive die connecting a left-most TSV to a central TSV of the passive die.

The plurality of passive dies 330 may each include one or more conductive lines in a BEOL metal layer 532 to facilitate signal lateral transmission from the left-most through-silicon vias (e.g., a first of M through-silicon vias) to a central through-silicon via(s) placed and aligned under the controller die 550 (e.g. an (M×N+1)-th through-silicon via). The signals may then transmit to subsequent tiers and be collected by the controller die 550. The base die 510 may be connected to a central through-silicon via of the base passive die 530 through an RDL 503 (e.g. a Fan-Out RDL).

Alternatively, the semiconductor device 300b may not include the base core die 510 and the corresponding base passive die 530, but the first core die 320(1st) of the plurality core dies 320 may act as a base die and the first passive die 330 (1st) of the plurality of passive dies act as a bass passive die. The plurality of core dies 320 may be similarly connected to the controller die 550 through the plurality of passive dies 330 by the plurality of through-silicon vias of the plurality of passive dies 530, i.e. through a metal line in a metal layer (e.g., BEOL) of each corresponding passive die connecting a left-most through-silicon via to a central through-silicon via of the passive die.

FIG. 6 is a flow chart showing a process 600 for making a semiconductor device 100, 200, 300 (e.g., memory unit) according to various aspects of the present disclosure.

According to various aspects of the present disclosure, the process 600 may include preparing a plurality of core dies (at step 604), including first to Nth core dies (e.g., memory dies); preparing a plurality of passive dies (e.g., TSV dies) (at step 606), including first to Nth passive dies, each of the plurality of passive dies corresponding to a respective core die of the plurality of core dies and including a plurality of through-silicon vias configured to connect the plurality of core dies with a controller die.

According to various aspects of the present disclosure, the process 600 may further include placing the plurality of core dies and the corresponding plurality of passive dies into a vertical stack to form first to Nth tiers in a manner that the respective core die of the plurality of core dies and the corresponding passive die of the plurality of passive die are arranged side-by-side horizontally in each tier of the first to Nth tiers. The plurality of core dies and the plurality of passive dies may be placed faced-down into vertical stacks as the first to Nth tiers in a manner that for each k, 2≤k≤N, the kth core die is shifted by a predetermined displacement from the k−1 core die. The kth core die may be connected to a through-silicon via of the plurality of through-silicon vias of the (k−1)th passive die of the plurality of passive dies.

According to various aspects of the present disclosure, the process 600 may further include preparing a controller die; preparing a base passive die corresponding to the controller die; and arranging the controller die and the corresponding base passive die horizontally side-by-side. Placing the plurality of core dies and the corresponding plurality of passive dies into the first to Nth tiers may include arranging the plurality of core dies and the corresponding plurality of passive dies over the base die and the corresponding base passive die, and the first core die being shifted by the predetermined displacement from the base die.

According to various aspects of the present disclosure, the process 600 may further include preparing a controller die and placing the controller die on top of the Nth passive die of the plurality of passive dies. The process 600 may further include fabricating an interconnect in each of the plurality of passive dies connecting a first through-silicon via with a last through-silicon via of the same passive die of the plurality of passive dies.

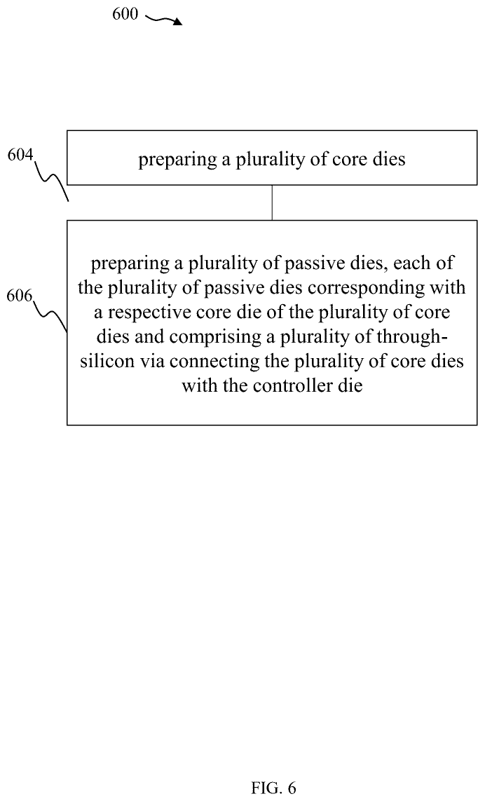

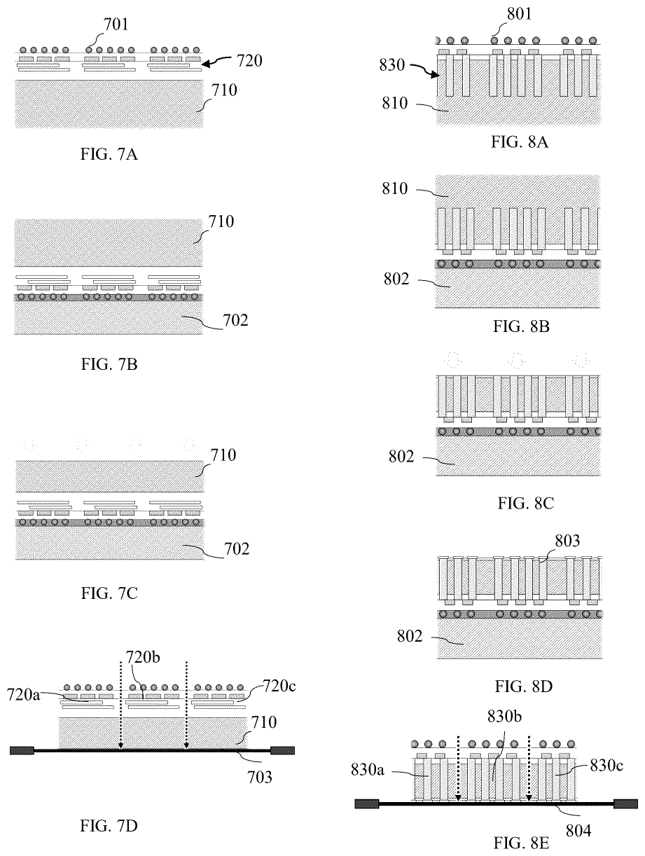

FIGS. 7A to 7D show schematic diagrams for fabricating a plurality of core dies/controller die/base die according to various aspects of the present disclosure.

FIG. 7A shows u-bump formation process. The u-bump formation process may include the creation of tiny solder bumps 701, also known as micro-bumps, for connecting dies 720 (e.g. core dies, controller die or base die) fabricated on a wafer 710 (e.g. a DRAM wafer). The μ-bump formation process may involve several steps: starting with Physical Vapor Deposition (PVD) of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form the bumps 701; and descumming to clean the surface.

FIG. 7B shows carrier bond process. The carrier bond process may provide temporary support for wafers during various fabrication processes such as thinning, etching, and deposition. The carrier bond process may involve attaching the wafer 710 to a carrier substrate 702, typically made of materials like glass or silicon, using a temporary adhesive such as thermal release tape or UV-curable adhesive. The carrier bond process may ensure mechanical stability and precise alignment, preventing damage to the thin, fragile wafers. The carrier bond process may include edge trimming to remove excess material from the edges of the wafer 710 using mechanical or chemical methods, TOK spin-coating that applies a uniform thin film of photoresist or other materials onto the wafer surface, and tungsten carbide (W2C) bonding process that involves depositing a thin layer of tungsten carbide onto the wafer or die surfaces and then applying pressure and heat to form a strong bond.

FIG. 7C shows backside grinding process. The backside grinding process may include two steps: background taping and backside grinding. The background taping may be the process of applying a protective adhesive tape to the front side of the wafer 710, ensuring the delicate circuitry is shielded from mechanical stress and contamination during grinding. Following this, backside grinding may thin the wafer 710 from the backside to the desired thickness through coarse and fine grinding stages. Coarse grinding may rapidly reduce the wafer's thickness using a diamond wheel, while fine grinding may achieve the precise final thickness and a smooth surface.

FIG. 7D shows de-bonding and die saw process. The de-bonding and die saw process may involve several steps to transform the fabricated dies 720 into functional electronic components ready for integration into devices. Initially, the fabricated dies 720 may undergo de-bonding to separate them from the carrier 702. These individual dies 720a, 720b, 720c may be then carefully mounted onto frames 703 to provide structural support. Subsequent steps may include cleaning off residual adhesives to ensure pristine surfaces for further processing. Non-conductive film (NCF) lamination may follow, where layers are bonded using specialized techniques like laser grooving and vias (LGV) to facilitate electrical connections and mechanical support. Finally, die sawing may precisely cut the assembled components into individual dies 720a, 720b, 720c, ensuring each is ready for packaging and integration into electronic products.

FIGS. 8A to 8E show schematic diagrams for fabricating a plurality of passive dies, each of which has a plurality of through-silicon vias according to various aspects of the present disclosure.

FIG. 8A shows u-bump formation process. The u-bump formation process may include the creation of tiny solder bumps 801 for connecting dies 830 (e.g. passive dies) fabricated on a wafer 810. The μ-bump formation process may involve several steps: starting with Physical Vapor Deposition (PVD) of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form the bumps 801; and descumming to clean the surface.

FIG. 8B shows carrier bond process. The carrier bond process may provide temporary support for wafers during various fabrication processes such as thinning, etching, and deposition. The carrier bond process may involve attaching the wafer 810 to a carrier substrate 802, typically made of materials like glass or silicon, using a temporary adhesive such as thermal release tape or UV-curable adhesive. The carrier bond process may ensure mechanical stability and precise alignment, preventing damage to the thin, fragile wafers. The carrier bond process may include edge trimming to remove excess material from the edges of the wafer 810 using mechanical or chemical methods, TOK spin-coating that applies a uniform thin film of photoresist or other materials onto the wafer surface, and tungsten carbide (W2C) bonding process that involves depositing a thin layer of tungsten carbide onto the wafer or die surfaces and then applying pressure and heat to form a strong bond.

FIG. 8C shows backside grinding and isolation process. The backside grinding may include two steps: background taping and backside grinding. The background taping may be the process of applying a protective adhesive tape to the front side of the wafer 810, ensuring the delicate circuitry is shielded from mechanical stress and contamination during grinding. Following this, backside grinding may thin the wafer 810 from the backside to the desired thickness through coarse and fine grinding stages. Coarse grinding may rapidly reduce the wafer's thickness using a diamond wheel, while fine grinding may achieve the precise final thickness and a smooth surface. The isolation process may include silicon etching of selectively removing silicon material from a wafer's surface or structure to create through-silicon vias 803, oxide deposition involving growing a layer of silicon dioxide (SiO₂) on the surface of the wafer 810 and Chemical Mechanical Polishing (CMP) used for planarization, smoothing, and flattening the surface of the wafer 810 after multiple layers of materials have been deposited or etched.

FIG. 8D shows Under Bump Metallization (UBM) process. The UBM process may include PVD of a titanium Ti layer, typically around 1000 Angstroms thick, onto the wafer 810. Photolithography may follow where a pattern is transferred onto the substrate using light-sensitive photoresist materials, defining the layout of the semiconductor components. Next, electroplating may deposit a layer of nickel (Ni) approximately 4 micrometres thick onto the wafer 810, enhancing conductivity and structural integrity. After the desired patterns are defined, the photoresist layer may be stripped away, exposing the underlying wafer 810 for further processing. Finally, a seed layer, often including a thin conductive material like copper, may be selectively etched to remove excess material, ensuring precise alignment and connectivity for subsequent layers or components.

FIG. 8E shows de-bonding and die saw process. The de-bonding and die saw process may involve several steps to transform the fabricated dies 830 into functional electronic components ready for integration into devices. Initially, the fabricated dies 830 may undergo de-bonding to separate them from the carrier 802. These individual dies 830a, 830b, 830c may be then carefully mounted onto frames 804 to provide structural support. Subsequent steps may include cleaning off residual adhesives to ensure pristine surfaces for further processing. Non-conductive film (NCF) lamination may follow, where layers are bonded using specialized techniques like laser grooving and vias (LGV) to facilitate electrical connections and mechanical support. Finally, die sawing may precisely cut the assembled components into individual dies 830a, 830b, 830c, ensuring each is ready for packaging and integration into electronic products.

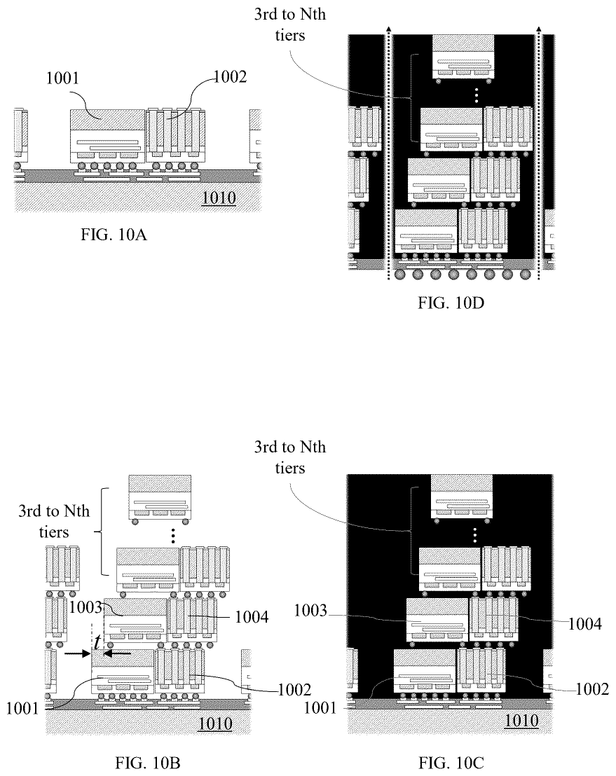

The individual core dies, controller dies, base dies and passive dies obtained by the processes described with reference to FIGS. 7A to 7D and 8A to 8E are assembled by the processes described below with reference to FIGS. 9A to 9E and 10A to 10D to form the described semiconductor devices.

FIGS. 9A to 9G show schematic diagrams for fabricating a semiconductor device according to various aspects of the present disclosure. The semiconductor device may be a memory unit.

FIG. 9A shows a process of fabricating Fan-out redistribution layer (FO-RDL) 991. The process may begin with the application of polyimide coating, providing insulation and protection. Photolithography may then define intricate patterns on the polyimide layer using light-sensitive photoresist materials. After curing to stabilize the polyimide, titanium (Ti) (e.g. 1000 angstroms) and copper (Cu) (e.g. 3000 angstroms) may be sequentially deposited using PVD, forming adhesion layers and conductive traces, respectively. Additional photolithography steps may refine these layers, followed by electroplating to build up copper thickness and photoresist stripping to reveal the patterned traces. Etching of the seed layer may ensure precise alignment and connectivity for subsequent layers. This process may be repeated for each RDL.

FIG. 9B shows a process of fabrication U-pads 981. The process may begin with applying a polyimide coating onto the substrate, providing electrical insulation and physical protection. Photolithography may follow, where patterns are defined on the polyimide layer using light-sensitive photoresist materials, for guiding subsequent metallization steps. The polyimide may be then cured to stabilize its structure and optimize its properties for semiconductor applications. Next, titanium (Ti) and copper (Cu) may be sequentially deposited using PVD, with titanium serving as an adhesion layer and copper forming the conductive traces for interconnections. Additional photolithography steps may refine the copper layer, defining intricate circuit patterns. Electroplating may be employed to increase the thickness of the copper traces, ensuring they can efficiently conduct electrical currents. Subsequently, the photoresist layer may be stripped away, leaving behind the desired patterned copper traces. Etching of the seed layer may complete the process, ensuring precise alignment and connectivity for subsequent layers or components.

FIG. 9C shows a placement process of a first core die (or a first control die or a first base die) 901 and a first passive die 902. The placement process may include Pick-N-Press process and reflow soldering process. The Pick-N-Press process may involve automated machinery that picks up the dies from supply sources and accurately positions them onto designated spots on the FO-RDL. In the context of various aspects, the Pick-N-Press process may include placing the first core die (or the first control die or the first base die) 901 and the corresponding first passive die 902 horizontally side-by-side in a respective tier. The reflow soldering process may create electrical connections between the dies and the FO-RDL. It may begin with applying solder paste, a mixture of solder alloy and flux, onto the U-pads of the FO-RDL. The assembled board may then pass through a reflow oven where it undergoes controlled heating stages. The solder paste may melt, flow, and solidify to securely bond the dies to the FO-RDL, forming robust solder joints.

FIG. 9D shows a molding process and a process of fabricating a second FO-RDL 992. The molding process may involve encapsulating the dies within a protective material to ensure their durability, reliability, and functionality. The second FO-RDL may be fabricated as hereinbefore. The RDLs may include lateral metal lines 993 that are used to connect core dies with passive dies as shown in FIG. 9G′. The RDLs may be referred as interposers used to connect between tiers of the semiconductor device.

FIG. 9E shows placement process of a second core die 903 and a second passive die 904. The second core die 903 and the second passive die 904 may be stacked vertically over the first core die 901 and the first passive die 902, respectively, and aligned therewith.

FIG. 9F shows further placement process of 3rd to Nth core dies and 3rd to Nth passive dies. The 3rd to Nth core dies may be stacked vertically over the first core die 901 and the second core die 903, and the 3rd to Nth passive dies may be stacked vertically over the first passive die 902 and the second passive die 904. The 3rd to Nth core dies and the 3rd to Nth passive dies may be aligned with the first core die 901 and the second core die 903, and the first passive die 902 and the second passive die 904.

According to various aspects of the present disclosure, the first core die 901, the second core die 903 and the 3rd to Nth core dies may be obtained by the process as described with reference to FIGS. 7A to 7D and be identical. The core dies may be void of through-silicon vias. The first passive die 902, the second passive die 904 and the 3rd to Nth passive dies may be obtained by the process as described with reference to FIGS. 8A to 8E and be identical. The passive dies may include through-silicon vias connecting the core dies to a controller die.

FIG. 9G shows carrier de-bonding and bump formation processes. The fabricated semiconductor device may undergo de-bonding to separate it from the carrier 910 and bump formation for electrical connection. Controlled Collapse Chip Connection (C4 bumps) or other pin-out technologies like wire bonding may be used for bump formation. The bump formation process may involve several steps: starting with PVD of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form bumps; and descumming to clean the surface.

FIG. 9G′ shows an example of the semiconductor device as shown FIG. 9G wherein a controller die 970 is fabricated at the base tier. The example semiconductor device may include the controller die 970; a plurality of core dies 971, 973, . . . , 97N; and a plurality of passive dies 972, 974, 976, . . . , 97N+1 (not shown). The controller die 970 may be associated with the first passive die 972 in the base tier. The first core die 971 may be associated with the second passive die 974 in the first tier above the base tier; the second core die 973 may be associated with the third passive die 976 in the second tier above the first tier; and so forth. Each of the plurality of passive dies 972, 974, 976, . . . , 97N+1, may include a plurality of through-silicon vias, connecting the plurality of core dies 971, 973, . . . , 97N with the controller die 970. The first passive die 972 may include a plurality of through-silicon vias (e.g. N through-silicon vias), and a respective through-silicon via of the plurality of through-silicon vias may connect a respective core die with the controller die 970 (e.g. through metal lines, e.g. the metal 993 as shown FIG. 9D).

Each of the plurality of passive dies 972, 974, 976, . . . , 97N+1, may include the plurality of through-silicon vias (e.g. N through-silicon vias), and a respective through-silicon via of the plurality of through-silicon vias may connect (e.g. facilitate to connect) a respective core die with the controller die 970 (e.g. through metal lines, e.g. the metal 993 as shown FIG. 9D). For example, a first connection path 981 may be formed through a first via of the plurality of through-silicon vias of the first passive die 972 to connect the core die 971 to the controller die 970; a second connection path 982 may be formed through second vias of each of the plurality of through-silicon vias of the first and second passive dies 972, 974, to connect the second core die 973 to the controller die 970; . . . ; an Nth connection path 98N may be formed through last vias of each of the plurality of through-silicon vias of the plurality of passive dies 972, 974, 976, . . . , 97N, to connect the core die 97N to the controller die 970. In other words, in the context of the controller die placed at the first tier, a core die in a subsequent tier (e.g. i-th tier) may be connected to the controller die through the lateral metal line of that tier (e.g. metal line 993 for the second tier) and through through-silicon vias (e.g. (i−1)-th via) of the passive dies in previous tiers (e.g. 1st to (i−1)-th tiers).

FIGS. 10A to 10D show schematic diagrams for making a semiconductor device according to various aspects of the present disclosure. The semiconductor device may be a memory unit.

FIG. 10A show similar placement process of a first core die (or a first control die or a first base die) 1001 and a first passive die 1002 as FIG. 9C. The process may include placing the first core die (or the first control die or the first base die) 1001 and the corresponding first passive die 1002 horizontally side-by-side in a respective tier. The process for making the semiconductor device may also include the processes shown in FIGS. 9A and 9B which are omitted here in the interest of brevity.

FIG. 10B shows a placement process of a second core die 1003 and a second passive die 1004 and further placement process of 3rd to Nth core dies and 3rd to Nth passive dies. The second core die 1003 and the second passive die 1004 may be stacked vertically over the first core die 1001 and the first passive die 1002 with an offset (denoted as t in FIG. 10B). That may mean that the second core die 1003 is stacked vertically over the first core die 1001 and the first passive die 1002. The second core die 1003 may connect to a through-silicon via of the first passive die 1002. Likewise, for each k, 2≤k≤N, the kth core die may be shifted by an offset t from the k−1 core die and the kth core die may be connected to a through-silicon via of the (k−1)th passive die.

According to various aspects of the present disclosure, the first core die 1001, the second core die 1003 and the 3rd to Nth core dies may be obtained by the process as described with reference to FIGS. 7A to 7D and be identical. The core dies may be void of through-silicon vias. The first passive die 1002, the second passive die 1004 and the 3rd to Nth passive dies may be obtained by the process as described with reference to FIGS. 8A to 8E and be identical. The passive dies may include through-silicon vias connecting the core dies to a controller die.

FIG. 10C shows molding process. The molding process may involve encapsulating the tiers of dies within a protective material to ensure their durability, reliability, and functionality.

FIG. 10D shows carrier de-bonding and bump formation processes. The fabricated semiconductor device may undergo de-bonding to separate it from the carrier 1010 and bump formation for electrical connection. Controlled Collapse Chip Connection (C4 bumps) or other pin-out technologies like wire bonding may be used for bump formation. The bump formation process may involve several steps: starting with PVD of Titanium (Ti) at 1,000 angstroms and PVD of Copper (Cu) at 3,000 angstroms to create a seed layer; followed by photolithography to define the bump locations; electroplating to build up the metal (e.g. Cu); stripping the photoresist; etching away the unnecessary seed layer; reflowing to form bumps; and descumming to clean the surface.

The following examples pertain to various aspects of the present disclosure.

Example 1 is a semiconductor device, including: a plurality of core dies, including first to Nth core dies; and a plurality of passive dies, including first to Nth passive dies, each of the plurality of passive dies corresponding to one respective core die of the plurality of core dies, wherein N being an integer greater than or equal to 2, wherein each of the plurality of passive dies includes a plurality of through-silicon vias configured to connect the plurality of core dies with a controller die, and wherein the plurality of core dies and the plurality of passive dies are arranged vertically into first to Nth tiers in a manner that each tier of the first to Nth tiers includes a core die of the plurality of core dies and a corresponding passive die of the plurality of passive die placed side-by-side horizontally.

In Example 2, the subject matter of Example 1 may optionally include for each integer k, 2≤k≤N, the kth core die is shifted by a predetermined horizontal displacement from the (k−1)th core die.

In Example 3, the subject matter of Example 2 may optionally include the kth core die is connected to a through-silicon via of the plurality of through-silicon vias of the (k−1)th passive die of the plurality of passive dies.

In Example 4, the subject matter of any of Examples 1-3 may optionally include the controller die; a base passive die corresponding to the controller die in a manner that the controller die and the corresponding base passive die are arranged side-by-side horizontally, wherein the first core die is shifted by the horizontal predetermined displacement from the controller die.

In Example 5, the subject matter of any of Examples 1-3 may optionally include the controller die; wherein the controller die is placed on top of the Nth passive die of the plurality of passive dies.

In Example 6, the subject matter of any of Examples 1-5 may optionally include each of the plurality of passive dies includes an interconnect connecting a first through-silicon via with a central through-silicon via of a same passive die of the plurality of passive dies.

In Example 7, the subject matter of any of Examples 1-6 may optionally include each of the plurality of passive dies includes at least 2xNxM through-silicon vias, M being an integer greater than or equal to 1.

In Example 8, the subject matter of Example 3 may optionally include in a portion where the kth passive die overlaps the (k−1)th passive die, a through-silicon via of a plurality of through-silicon vias of the (k−1)th passive die connects to an aligned through-silicon via of a plurality of through-silicon vias of the kth passive die, and a first through-silicon via of the plurality of through-silicon vias of the (k−1)th passive die connects to the kth core die of the plurality of core dies.

In Example 9, the subject matter of any of Examples 1-8 may optionally include the plurality of core dies are void of through-silicon vias.

In Example 10, the subject matter of any of Examples 1-9 may optionally include the plurality of core dies are identical.

Example 11 is a process for making a semiconductor device, e.g., the semiconductor device according to any one of Examples 1-10, including: preparing a plurality of core dies, including first to Nth core dies; preparing a plurality of passive dies, including first to Nth passive dies, each of the plurality of passive dies corresponding to one respective core die of the plurality of core dies and including a plurality of through-silicon via configured to connect the plurality of core dies with a controller die, and arranging the plurality of core dies and the plurality of passive dies vertically into first to Nth tiers in a manner that each tier of the first to Nth tiers includes a core die of the plurality of core dies and a corresponding passive die of the plurality of passive die placed side-by-side horizontally.

In Example 12, the subject matter of Example 11 may optionally include for each k, 2≤k≤N, the kth core die is shifted by a horizontal predetermined displacement from the (k−1)th core die.

In Example 13, the subject matter of Example 12 may optionally include the kth core die is connected to a through-silicon via of a plurality of through-silicon vias of the (k−1)th passive die of the plurality of passive dies.

In Example 14, the subject matter of any of Examples 11-13 may optionally include preparing the controller die; preparing a base passive die corresponding to the controller die; and placing the controller die and the corresponding base passive die side-by-side, wherein arranging the plurality of core dies and the plurality of passive dies vertically into first to Nth tiers includes arranging the plurality of core dies and the corresponding plurality of passive dies over the controller die and the corresponding base passive die, and wherein the first core die is shifted by the horizontal predetermined displacement from the controller die.

In Example 15, the subject matter of any of Examples 11-13 may optionally include preparing the controller die; and placing the controller die on top of the Nth passive die of the plurality of passive dies.

In Example 16, the subject matter of any of Examples 11-15 may optionally include fabricating an interconnect in each of the plurality of passive dies connecting a first through-silicon via with a central through-silicon via of a same passive die of the plurality of passive dies.

In Example 17, the subject matter of any of Examples 11-16 may optionally include each of the plurality of passive dies includes at least 2xNxM through-silicon vias, M being an integer greater than or equal to 1.

In Example 18, the subject matter of any of Examples 11-15 may optionally include disposing a plurality of interposers between tiers of the first to Nth tiers.

In Example 19, the subject matter of any of Examples 11-18 may optionally include the plurality of core dies are void of through-silicon vias.

In Example 20, the subject matter of any of Examples 11-19 may optionally include the plurality of core dies are identical.

Example 21 is a system, including: at least one processor; and at least one memory coupled to the at least one processor, wherein at least one of the at least one processor and at least one memory includes a semiconductor device according to any of Examples 1-10. For example, the semiconductor device of Example 21 may include: a controller die; a plurality of core dies, including first to Nth core dies; and a plurality of passive dies, including first to Nth passive dies, each of the plurality of passive dies corresponding to one respective core die of the plurality of core dies, wherein N being an integer greater than or equal to 2, wherein each of the plurality of passive dies includes a plurality of through-silicon vias configured to connect the plurality of core dies with the controller die, and wherein the plurality of core dies and the plurality of passive dies are arranged vertically into first to Nth tiers in a manner that each tier of the first to Nth tiers includes a core die of the plurality of core dies and a corresponding passive die of the plurality of passive die placed side-by-side horizontally.

In Example 22, the subject matter of Example 21 may optionally include for each integer k, 2≤k≤N, the kth core die is shifted by a predetermined horizontal displacement from the (k−1)th core die.

In Example 23, the subject matter of Example 22 may optionally include the kth core die is connected to a through-silicon via of the plurality of through-silicon vias of the (k−1)th passive die of the plurality of passive dies.

In Example 24, the subject matter of Example 23 may optionally include the controller die; a base passive die corresponding to the controller die in a manner that the controller die and the corresponding base passive die are arranged side-by-side horizontally, wherein the first core die is shifted by the horizontal predetermined displacement from the controller die.

In Example 25, the subject matter of any of Examples 21-23 may optionally include wherein the controller die is placed on top of the Nth passive die of the plurality of passive dies.

In Example 26, the subject matter of any of Examples 21-25 may optionally include each of the plurality of passive dies includes an interconnect connecting a first through-silicon via with a central through-silicon via of a same passive die of the plurality of passive dies.

In Example 27, the subject matter of Example 26 may optionally include each of the plurality of passive dies includes at least 2×N×M through-silicon vias, M being an integer greater than or equal to 1.

In Example 28, the subject matter of any of Examples 21-23 may optionally include in a portion where the kth passive die overlaps the (k−1)th passive die, a through-silicon via of a plurality of through-silicon vias of the (k−1)th passive die connects to an aligned through-silicon via of a plurality of through-silicon vias of the kth passive die, and a first through-silicon via of the plurality of through-silicon vias of the (k−1)th passive die connects to the kth core die of the plurality of core dies.

In Example 29, the subject matter of any of Examples 21-28 may optionally include the plurality of core dies are void of through-silicon vias.

In Example 30, the subject matter of any of Examples 21-29may optionally include the plurality of core dies are identical.

Example 31 is a non-transitory computer readable storage medium having instructions stored thereon that, when executed by a processor, cause a process for making a semiconductor device to be performed, the process according to any one of Examples 11 to 20. For example, the process may include: preparing a plurality of core dies, comprising first to Nth core dies; preparing a plurality of passive dies, comprising first to Nth passive dies, each of the plurality of passive dies corresponding to one respective core die of the plurality of core dies and comprising a plurality of through-silicon via configured to connect the plurality of core dies with a controller die, and arranging the plurality of core dies and the corresponding plurality of passive dies vertically into first to Nth tiers in a manner that each tier of the first to Nth tiers includes a core die of the plurality of core dies and a corresponding passive die of the plurality of passive die arranged side-by-side horizontally.

While this specification contains many details, these should not be understood as limitations on the scope of what may be claimed, but rather as descriptions of features specific to particular examples. Certain features that are described in this specification or shown in the drawings in the context of separate aspects can also be combined. Conversely, various features that are described or shown in the context of a single aspect can also be implemented in multiple aspects separately or in any suitable sub-combination.

Similarly, while steps/operations of the methods as described above are depicted in a particular order (e.g. as shown in the drawings), this should not be understood as requiring that such operations/steps be performed in the particular order shown or in sequential order, or that all illustrated operations be performed, to achieve desirable results. In certain circumstances, multitasking and parallel processing may be advantageous. For example, some operations/steps may occur in different orders and/or concurrently with other operations/steps apart from those illustrated and/or described herein. In addition, not all illustrated operations/steps may be required to implement one or more aspects or aspects described herein. Also, one or more of the steps depicted herein may be carried out in one or more separate acts and/or phases.

Moreover, the separation/integration of various system components in the aspects described above should not be understood as requiring such separation/integration in all aspects, and it should be understood that the described program components and systems can generally be integrated together in a single product or separated into multiple products.

A number of aspects have been described. Nevertheless, it will be understood that various modifications can be made. Accordingly, other aspects are within the scope of the following claims.

1. A semiconductor device, comprising:
a plurality of core dies, comprising first to Nth core dies; and
a plurality of passive dies, comprising first to Nth passive dies, each of the plurality of passive dies corresponding to one respective core die of the plurality of core dies,
wherein N being an integer greater than or equal to 2,
wherein each of the plurality of passive dies comprises a plurality of through-silicon vias configured to connect the plurality of core dies with a controller die, and
wherein the plurality of core dies and the plurality of passive dies are arranged vertically into first to Nth tiers in a manner that each tier of the first to Nth tiers includes a core die of the plurality of core dies and a corresponding passive die of the plurality of passive die placed side-by-side horizontally.

2. The semiconductor device of claim 1, wherein for each integer k, 2≤k≤N, the kth core die is shifted by a predetermined horizontal displacement from the (k−1)th core die.

3. The semiconductor device of claim 2, wherein the kth core die is connected to a through-silicon via of the plurality of through-silicon vias of the (k−1)th passive die of the plurality of passive dies.

4. The semiconductor device of claim 3, further comprising:
the controller die;
a base passive die corresponding to the controller die in a manner that the controller die and the corresponding base passive die are arranged side-by-side horizontally,
wherein the first core die is shifted by the horizontal predetermined displacement from the controller die.

5. The semiconductor device of claim 3, further comprising:
the controller die;
wherein the controller die is placed on top of the Nth passive die of the plurality of passive dies.

6. The semiconductor device of claim 5, wherein each of the plurality of passive dies comprises an interconnect connecting a first through-silicon via with a central through-silicon via of a same passive die of the plurality of passive dies.

7. The semiconductor device of claim 6, wherein each of the plurality of passive dies comprises at least 2×N×M through-silicon vias, M being an integer greater than or equal to 1.

8. The semiconductor device of claim 3, wherein in a portion where the kth passive die overlaps the (k−1)th passive die, a through-silicon via of a plurality of through-silicon vias of the (k−1)th passive die connects to an aligned through-silicon via of a plurality of through-silicon vias of the kth passive die, and a first through-silicon via of the plurality of through-silicon vias of the (k−1)th passive die connects to the kth core die of the plurality of core dies.

9. A process for making a semiconductor device, comprising:
preparing a plurality of core dies, comprising first to Nth core dies;
preparing a plurality of passive dies, comprising first to Nth passive dies, each of the plurality of passive dies corresponding to one respective core die of the plurality of core dies and comprising a plurality of through-silicon via configured to connect the plurality of core dies with a controller die, and
arranging the plurality of core dies and the plurality of passive dies vertically into first to Nth tiers in a manner that each tier of the first to Nth tiers includes a core die of the plurality of core dies and a corresponding passive die of the plurality of passive die placed side-by-side horizontally.

10. The process of claim 9, wherein for each k, 2≤k≤N, the kth core die is shifted by a horizontal predetermined displacement from the (k−1)th core die.

11. The process of claim 10, wherein the kth core die is connected to a through-silicon via of a plurality of through-silicon vias of the (k−1)th passive die of the plurality of passive dies.

12. The process of claim 11, further comprising:
preparing the controller die;
preparing a base passive die corresponding to the controller die; and
placing the controller die and the corresponding base passive die side-by-side,
wherein arranging the plurality of core dies and the plurality of passive dies vertically into first to Nth tiers comprises arranging the plurality of core dies and the corresponding plurality of passive dies over the controller die and the corresponding base passive die, and
wherein the first core die is shifted by the horizontal predetermined displacement from the controller die.

13. The process of claim 11, further comprising:
preparing the controller die; and
placing the controller die on top of the Nth passive die of the plurality of passive dies.

14. The process of claim 13, further comprising:
fabricating an interconnect in each of the plurality of passive dies connecting a first through-silicon via with a central through-silicon via of a same passive die of the plurality of passive dies.

15. The process of claim 14, wherein each of the plurality of passive dies comprises at least 2×N×M through-silicon vias, M being an integer greater than or equal to 1.

16. The process of claim 9, further comprising:
disposing a plurality of interposers between tiers of the first to Nth tiers.

17. A system, comprising:
at least one processor; and
at least one memory coupled to the at least one processor,
wherein at least one of the at least one processor and at least one memory comprises a semiconductor device, the semiconductor device comprises:
a controller die;
a plurality of core dies, comprising first to Nth core dies; and
a plurality of passive dies, comprising first to Nth passive dies, each of the plurality of passive dies corresponding to one respective core die of the plurality of core dies,
wherein N being an integer greater than or equal to 2,
wherein each of the plurality of passive dies comprises a plurality of through-silicon vias configured to connect the plurality of core dies with the controller die, and
wherein the plurality of core dies and the plurality of passive dies are arranged vertically into first to Nth tiers in a manner that each tier of the first to Nth tiers includes a core die of the plurality of core dies and a corresponding passive die of the plurality of passive die placed side-by-side horizontally.

18. The system of claim 17, wherein for each integer k, 2≤k≤N, the kth core die is shifted by a predetermined horizontal displacement from the (k−1)th core die.

19. The system of claim 17, wherein the kth core die is connected to a through-silicon via of the plurality of through-silicon vias of the (k−1)th passive die of the plurality of passive dies.

20. The system of claim 19, wherein in a portion where the kth passive die overlaps the (k−1)th passive die, a through-silicon via of a plurality of through-silicon vias of the (k−1)th passive die connects to an aligned through-silicon via of a plurality of through-silicon vias of the kth passive die, and a first through-silicon via of the plurality of through-silicon vias of the (k−1)th passive die connects to the kth core die of the plurality of core dies.
